(19) United States
(12) Patent Application Publication
(10) Pub. No.: US 2009/0277587 A1
(43) Pub. Date: Nov. 12, 2009

(54) FLOWABLE DIELECTRIC EQUIPMENT AND PROCESSES

(75) Inventors: Dmitry Lubomirsky, Cupertino, CA (US); Qiwei Liang, Fremont, CA (US); Jang Gyoo Yang, San Jose, CA (US)

Correspondence Address: TOWNSEND AND TOWNSEND AND CREW LLP, TWO EMBARCADERO CENTER, EIGHTH FLOOR, SAN FRANCISCO, CA, 94111-3834, US

(73) Assignee: Applied Materials, Inc., Santa Clara, CA (US)

(21) Appl. No.: 12/210,940

(22) Filed: Sep. 15, 2008

Related U.S. Application Data
(60) Provisional application No. 61/052,080, filed on May 9, 2008.

(51) Int. Cl. H01L 21/3065; H01L 21/306

(52) U.S. Cl. 156/345.34; 118/723 R; 156/345.35; 118/723 ER; 118/719

(57) ABSTRACT

Substrate processing systems are described that may include a processing chamber having an interior capable of holding an internal chamber pressure different from an external chamber pressure. The systems may also include a remote plasma system operable to generate a plasma outside the interior of the processing chamber. In addition, the systems may include a first process gas channel operable to transport a first process gas from the remote plasma system to the interior of the processing chamber, and a second process gas channel operable to transport a second process gas that is not treated by the remote plasma system. The second process gas channel has a distal end that opens into the interior of the processing chamber, and that is at least partially surrounded by the first process gas channel.

### CROSS-REFERENCES TO RELATED APPLICATIONS

This application claims the benefit of U.S. Provisional Patent Application No. 61/052,080 field May 9, 2008. This application is also related to U.S. patent application Ser. No. 11/754,858, filed May 29, 2007, and titled “PROCESS CHAMBER FOR DIELECTRIC GAPFILL.” The entire contents of both applications are herein incorporated by reference for all purposes.

### FIELD

This application relates to manufacturing technology solutions involving equipment, processes, and materials used in the deposition, patterning, and treatment of thin-films and coatings, with representative examples including (but not limited to) applications involving: semiconductor and dielectric materials and devices, silicon-based wafers and flat panel displays (such as TFTs).

### BACKGROUND

A conventional semiconductor processing system contains one or more processing chambers and a means for moving a substrate between them. A substrate may be transferred between chambers by a robotic arm which can extend to pick up the substrate, retract and then extend again to position the substrate in a different destination chamber. FIG. 1 shows a schematic of a substrate processing chamber. Each chamber has a pedestal shaft 105 and pedestal 110 or some equivalent way of supporting the substrate 115 for processing.

A pedestal can be a heater plate in a processing chamber configured to heat the substrate. The substrate may be held by a mechanical, pressure differential or electrostatic means to the pedestal between when a robot arm drops off the substrate and when an arm returns to pick up the substrate. Lift pins are often used to elevate the wafer during robot operations.

One or more semiconductor fabrication process steps are performed in the chamber, such as annealing the substrate or depositing or etching films on the substrate. Dielectric films are deposited into complex topologies during some processing steps. Many techniques have been developed to deposit dielectrics into narrow gaps including variations of chemical vapor deposition techniques which sometimes employ plasma techniques. High-density plasma (HDP)-CVD has been used to fill many geometries due to the perpendicular impingement trajectories of the incoming reactants and the simultaneous sputtering activity. Some very narrow gaps, however, have continued to develop voids due, in part, to the lack of mobility following initial impact. Reflowing the material after deposition can fill the void but, if the dielectric has a high reflow temperature (like SiO₂), the reflow process may also consume a non-negligible portion of a wafer's thermal budget.

By way of its high surface mobility, flow-able materials such as spin-on glass (SOG) have been useful in filling some of the gaps which were incompletely filled by HDP-CVD. SOG is applied as a liquid and cured after application to remove solvents, thereby converting material to a solid glass film. The gap-filling (gapfill) and planarization capabilities are enhanced for SOG when the viscosity is low. Unfortunately, low viscosity materials may shrink significantly during cure. Significant film shrinkage results in high film stress and delamination issues, especially for thick films.

Separating the delivery paths of two components can produce a flowable film during deposition on a substrate surface. FIG. 1 shows a schematic of a substrate processing system with separated delivery channels 125 and 135. An organo-silane precursor may be delivered through one channel and an oxidizing precursor may be delivered through the other. The oxidizing precursor may be excited by a remote plasma 145. The mixing region 120 of the two components occurs closer to the substrate 115 than alternative processes utilizing a more common delivery path. Since the films are grown rather than poured onto the surface, the organic components needed to decrease viscosity are allowed to evaporate during the process which reduces the shrinkage affiliated with a cure step. Growing films this way limits the time available for adsorbed species to remain mobile, a constraint which may result in deposition of nonuniform films. A baffle 140 may be used to more evenly distribute the precursors in the reaction region.

Gapfill capabilities and deposition uniformity benefit from high surface mobility which correlates with high organic content. Some of the organic content may remain after deposition and a cure step may be used. The cure may be conducted by raising the temperature of the pedestal 110 and substrate 115 with a resistive heater embedded in the pedestal.

### BRIEF SUMMARY

Disclosed embodiments include substrate processing systems that have a processing chamber and a substrate support assembly at least partially disposed within the chamber. Two gases (or two combinations of gases) are delivered to the substrate processing chamber by different paths. A process gas can be delivered into the processing chamber, excited in a plasma in a first plasma region, and pass through a showerhead into a second plasma region where it interacts with a silicon-containing gas and forms a film on the surface of a substrate. A plasma may be ignited in either the first plasma region or the second plasma region.

Choosing the orientation arbitrarily, the process gas can be introduced through a top of the processing chamber which forms a top plasma electrode. The showerhead forms a middle plasma electrode and the bottom of the processing chamber and/or the pedestal form the bottom electrode. The middle electrode can be chosen to substantially match the top or the bottom electrodes thereby determining the location of the plasma. During deposition, a plasma is ignited with the top and middle electrodes to form a plasma in the first plasma region. The potential of the middle electrode may be chosen to substantially match the top electrode, thereby creating a plasma in the second plasma region. A plasma in the second plasma region may help cure a deposited film but can also be used to clean the chamber. During a cleaning process, the gas present in the second plasma region may contain fluorine.

In disclosed embodiments, the process gas contains oxygen, hydrogen and/or nitrogen (e.g. oxygen (O₂), ozone (O₃), N₂O, NO, NO₂, NH₃, NₓH_{y} including N₂H₄, silane, disilane, TSA, DSA, . . . ) and after it passes the showerhead, it is combined with a silicon-containing precursor (e.g. silane, disilane, TSA, DSA, TEOS, OMCTS, TMDSO, . . . ) introduced into the second plasma region. The combination of reactants forms a film of film on a substrate. The film may be silicon oxide, silicon nitride, silicon oxycarbide or silicon oxynitride.

In additional disclosed embodiments, a treatment gas may be introduced (e.g. oxygen (O₂), ozone (O₃), N₂O, NO, NO₂, NₓH_{y} including N₂H₄, H₂, N₂, NH₃, and water vapor). The treatment gas may be introduced from the top of the processing chamber and excited in the first plasma region. Alternatively, the gas may be excited by a remote plasma before entering the first plasma region. This gas does not contribute appreciably to the film growth, but may be used to reduce hydrogen, carbon and fluorine content of the film while it is being grown or following growth. Hydrogen and nitrogen radicals induce a reduction in undesirable components of the growing film. Excited derivatives of the treatment gas assist the film by scavenging carbon and other atoms from the growing lattice, thereby reducing the contraction exhibited during the cure and the film stress present afterward.

In further embodiments, a treatment gas is delivered through showerhead, after being excited in a remote plasma or a plasma in the first plasma region, to the second plasma region after a chamber maintenance procedure (clean and/or season) to remove residual fluorine from the interior of the processing chamber.

The two plasmas can be a variety of frequencies but will generally be in the radio frequency (RF) range. The plasmas can be inductively or capacitively coupled. All parts of the chamber including the showerhead may be cooled by flowing water or another coolant through channels made in the parts.

Additional embodiments and features are set forth in part in the description that follows, and in part will become apparent to those skilled in the art upon examination of the specification or may be learned by the practice of the disclosed embodiments. The features and advantages of the disclosed embodiments may be realized and attained by means of the instrumentalities, combinations, and methods described in the specification.

### BRIEF DESCRIPTION OF THE DRAWINGS

A further understanding of the nature and advantages of the disclosed embodiments may be realized by reference to the remaining portions of the specification and the drawings.

FIG. 1 is a schematic of a prior art processing region within a deposition chamber for growing films with separate oxidizing and organo-silane precursors.

FIG. 2 is a perspective view of a process chamber with partitioned plasma generation regions according to disclosed embodiments.

FIG. 3A is a schematic of an electrical switch box according to disclosed embodiments.

FIG. 3B is a schematic of an electrical switch box according to disclosed embodiments.

FIG. 4A is a cross-sectional view of a process chamber with partitioned plasma generation regions according to disclosed embodiments.

FIG. 4B is a cross-sectional view of a process chamber with partitioned plasma generation regions according to disclosed embodiments.

FIG. 5 is a close-up perspective view of a gas inlet and first plasma region according to disclosed embodiments.

FIG. 6A is a perspective view of a dual-source lid for use with a processing chamber according to disclosed embodiments.

FIG. 6B is a cross-sectional view of a dual-source lid for use with a processing chamber according to disclosed embodiments.

FIG. 7A is a cross-sectional view of a dual-source lid for use with a processing chamber according to disclosed embodiments.

FIG. 7B is a bottom view of a showerhead for use with a processing chamber according to disclosed embodiments.

FIG. 8 is a substrate processing system according to disclosed embodiments.

FIG. 9 is a substrate processing chamber according to disclosed embodiments.

FIG. 10 is a flow chart of a deposition process according to disclosed embodiments.

FIG. 11 is a flow chart of a film curing process according to disclosed embodiments.

FIG. 12 is a flow chart of a chamber cleaning process according to disclosed embodiments.

In the appended figures, similar components and/or features may have the same reference label. Where the reference label is used in the specification, the description is applicable to any one of the similar components having the same reference label.

### DETAILED DESCRIPTION

Disclosed embodiments include substrate processing systems that have a processing chamber and a substrate support assembly at least partially disposed within the chamber. At least two gases (or two combinations of gases) are delivered to the substrate processing chamber by different paths. A process gas can be delivered into the processing chamber, excited in a plasma, and pass through a showerhead into a second plasma region where it interacts with a silicon-containing gas and forms a film on the surface of a substrate. A plasma can be ignited in either the first plasma region or the second plasma region.

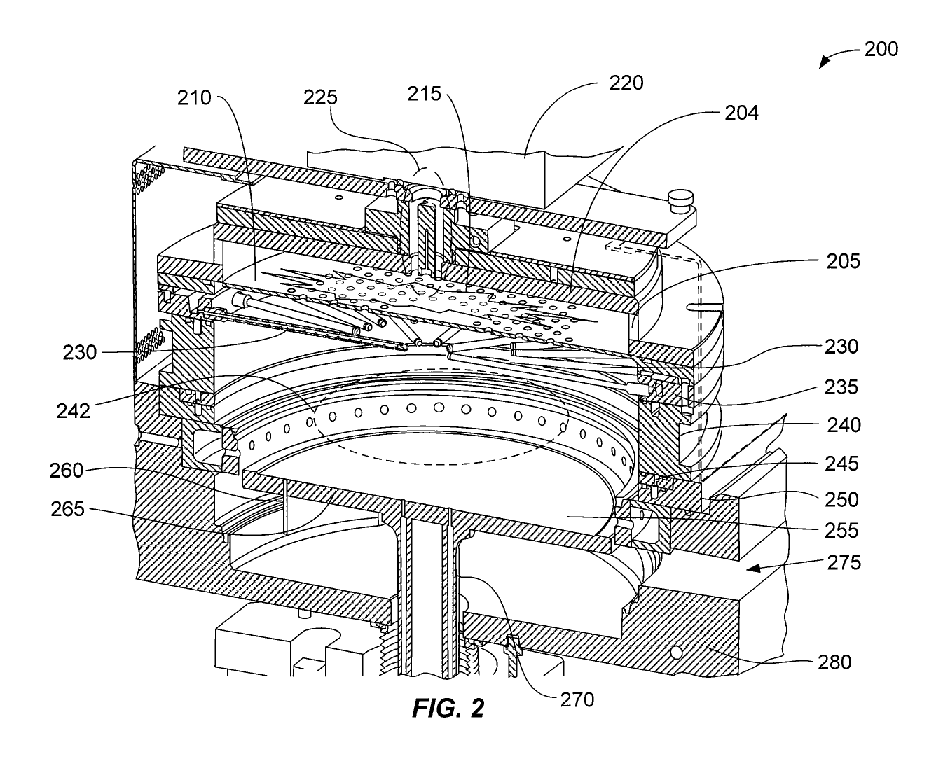

FIG. 2 is a perspective view of a process chamber with partitioned plasma generation regions which maintain a separation between multiple gas precursors. A process gas containing oxygen, hydrogen and/or nitrogen (e.g. oxygen (O₂), ozone (O₃), N₂O, NO, NO₂, NH₃, NₓH_{y} including N₂H₄, silane, disilane, TSA, DSA, . . . ) may be introduced through the gas inlet assembly 225 into a first plasma region 215. The first plasma region 215 may contain a plasma formed from the process gas. The process gas may also be excited prior to entering the first plasma region 215 in a remote plasma system (RPS) 220. Below the first plasma region 215 is a showerhead 210, which is a perforated partition (referred to herein as a showerhead) between the first plasma region 215 and a second plasma region 242. In embodiments, a plasma in the first plasma region 215 is created by applying AC power, possibly RF power, between a lid 204 and the showerhead 210, which may also be conducting.

In order to enable the formation of a plasma in the first plasma region, an electrically insulating ring 205 may be positioned between the lid 204 and the showerhead 210 to enable an RF power to be applied between the lid 204 and the showerhead 210. The electrically insulating ring 205 may be made from a ceramic and may have a high breakdown voltage to avoid sparking.

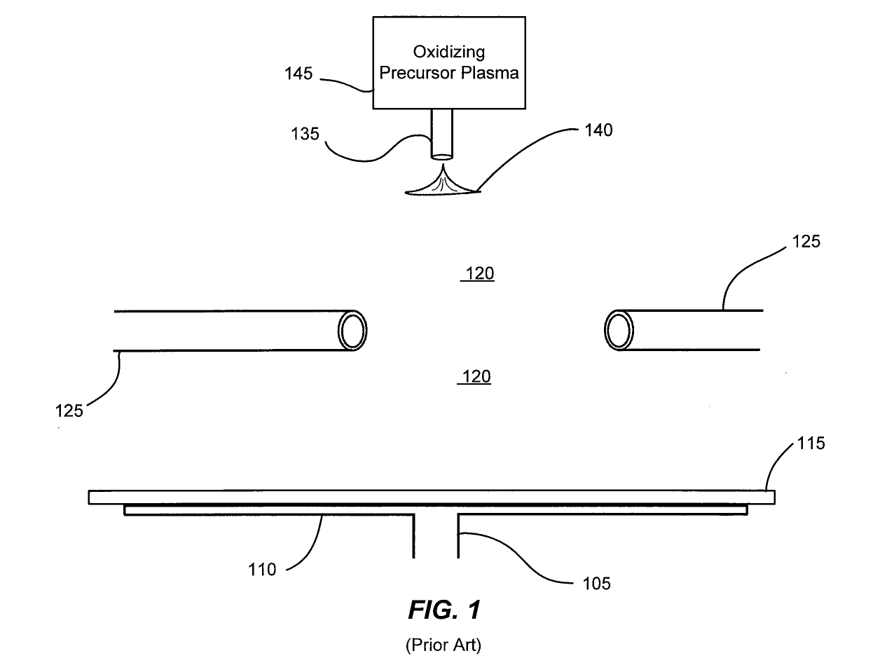

The second plasma region 242 may receive excited gas from the first plasma region 215 through holes in the showerhead 210. The second plasma region 242 may also receive gases and/or vapors from tubes 230 extending from a side 235 of the processing chamber 200. The gas from the first plasma region 215 and the gas from the tubes 230 are mixed in the second plasma region 242 to process the substrate 255. Igniting a plasma in the first plasma region 215 to excite the process gas, may result in a more uniform distribution of excited species flowing into the substrate processing region (second plasma region 242) than a method relying only on the RPS 145 and baffle 140 of FIG. 1. In disclosed embodiments, there is no plasma in the second plasma region 242.

Processing the substrate 255 may include forming a film on the surface of the substrate 255 while the substrate is supported by a pedestal 265 positioned within the second plasma region 242. The side 235 of the processing chamber 200 may contain a gas distribution channel which distributes the gas to the tubes 230. In embodiments, silicon-containing precursors are delivered from the gas distribution channel through the tubes 230 and through an aperture at the end of each tube 230 and/or apertures along the length of the tubes 230.

Note that the path of the gas entering the first plasma region 215 from the gas inlet 225 can be interrupted by a baffle (not shown, but analogous to the baffle 140 of FIG. 1) whose purpose here is to more evenly distribute the gas in the first plasma region 215. In some disclosed embodiments, the process gas is an oxidizing precursor (which may containing oxygen (O₂), ozone (O₃), . . . ) and after flowing through the holes in the showerhead, the process gas may be combined with a silicon-containing precursor (e.g. silane, disilane, TSA, DSA, TEOS, OMCTS, TMDSO, . . . ) introduced more directly into the second plasma region. The combination of reactants may be used to form a film of silicon oxide (SiO₂) on a substrate 255. In embodiments the process gas contains nitrogen (NH₃, NₓH_{y} including N₂H₄, TSA, DSA, N₂O, NO, NO₂, . . . ) which, when combined with a silicon-containing precursor may be used to form silicon nitride, silicon oxynitride or a low-K dielectric.

In disclosed embodiments, a substrate processing system is also configured so a plasma may be ignited in the second plasma region 242 by applying an RF power between the showerhead 210 and the pedestal 265. When a substrate 255 is present, the RF power may be applied between the showerhead 210 and the substrate 255. An insulating spacer 240 is installed between the showerhead 210 and the chamber body 280 to allow the showerhead 210 to be held at a different potential from the substrate 255. The pedestal 265 is supported by a pedestal shaft 270. A substrate 255 may be delivered to the process chamber 200 through a slit valve 275 and may be supported by lift pins 260 before being lowered onto the pedestal 265.

In the above description, plasmas in the first plasma region 215 and the second plasma region 242 are created by applying an RF power between parallel plates. In an alternative embodiment, either or both plasmas may be created inductively in which case the two plates may not be conducting. Conducting coils may be embedded within two electrically insulating plates and/or within electrically insulating walls of the processing chamber surrounding the region. Regardless of whether a plasma is capacitively coupled (CCP) or inductively coupled (ICP), the portions of the chamber exposed to the plasma may be cooled by flowing water through a cooling fluid channel within the portion. The shower head 210, the lid 204 and the walls 205 are water-cooled in disclosed embodiments. In the event that an inductively coupled plasma is used, the chamber may (more easily) be operated with plasmas in both the first plasma region and the second plasma region at the same time. This capability may be useful to expedite chamber cleaning.

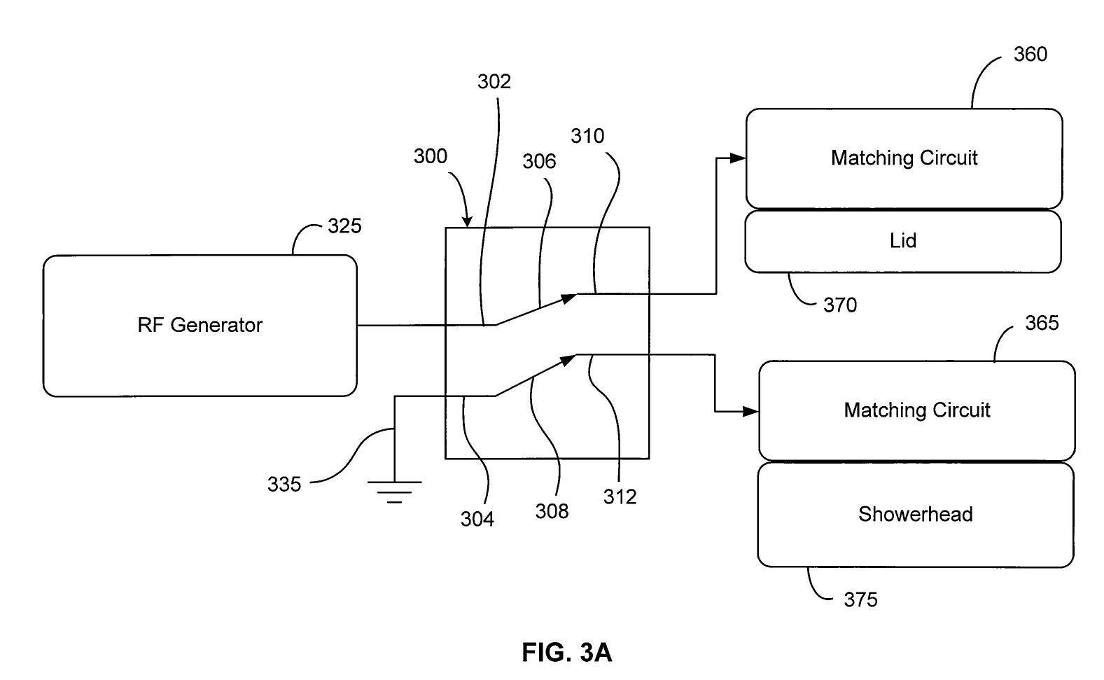

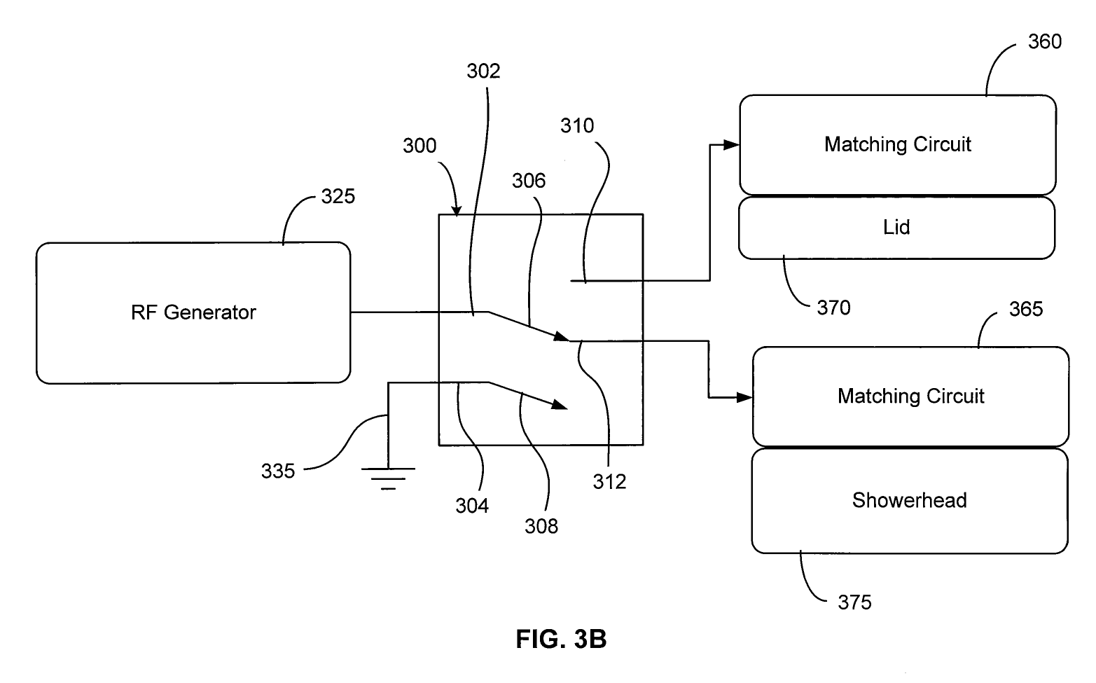

FIGS. 3A-B are electrical schematics of an electrical switch 300 which may result in a plasma in either the first plasma region or the second plasma region. In both FIGS. 3A and 3B the electrical switch 300 is a modified double-pole double-throw (DPDT). The electrical switch 300 can be in one of two positions. The first position is shown in FIG. 3A and the second position in FIG. 3B. The two connections on the left are electrical inputs to the processing chamber and the two connections on the right are output connections to components on the processing chamber. The electrical switch 300 may be located physically near or on the processing chamber but may also be distal to the processing chamber. The electrical switch 300 may be manually and/or automatically operated. Automatic operation may involve the use of one or more relays to change the status of the two contacts 306, 308. The electrical switch 300 in this disclosed embodiment is modified from a standard DPDT switch in that exactly one output 312 can be contacted by each of the two contacts 306, 308 and the remaining output can only be contacted by one contact 306.

The first position (FIG. 3A) enables a plasma to be created in the first plasma region and results in little or no plasma in the second plasma region. The chamber body, pedestal and substrate (if present) are typically at ground potential in most substrate processing systems. In disclosed embodiments, the pedestal is grounded regardless of the electrical switch 300 position. FIG. 3A shows a switch position which applies an RF power to the lid 370 and grounds (in other words applies 0 volts to) the showerhead 375. This switch position may correspond to the deposition of a film on the substrate surface.

The second position (FIG. 3B) enables a plasma to be created in the second plasma region. FIG. 3B shows a switch position which applies an RF power to the showerhead 375 and allows the lid 370 to float. An electrically floating lid 370 results in little or no plasma present in the first plasma region. This switch position may correspond to the treatment of a film after deposition or to a chamber cleaning procedure in disclosed embodiments.

Two impedance matching circuits 360, 365 appropriate for the AC frequency(s) output by the RF source and aspects of the lid 370 and showerhead 375 are depicted in both FIGS. 3A and 3B. the impedance matching circuits 360, 365 may reduce the power requirements of the RF source by reducing the reflected power returning to the RF source. Again, the frequencies may be outside the radio frequency spectrum in some disclosed embodiments.

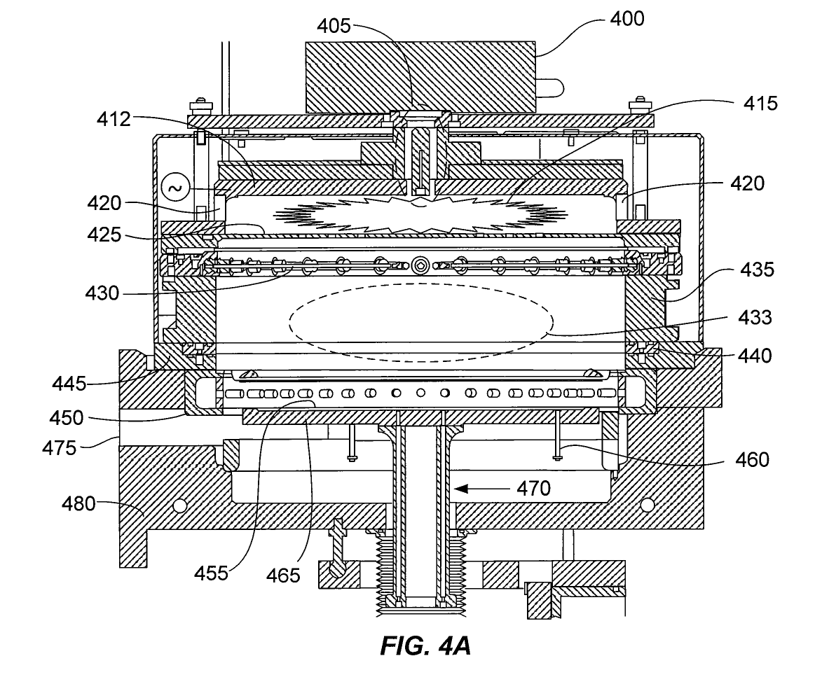

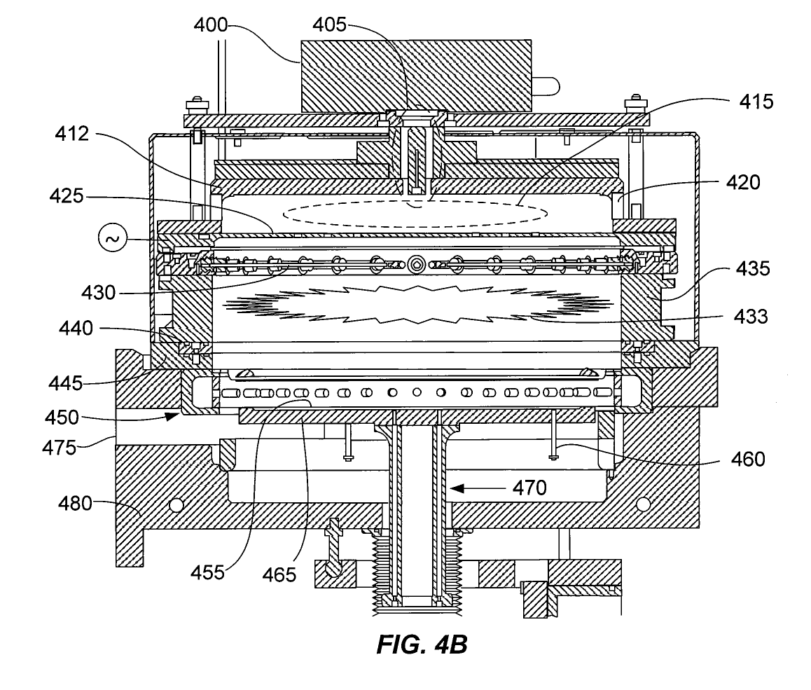

FIGS. 4A-B are cross-sectional views of a process chamber with partitioned plasma generation regions according to disclosed embodiments. During film deposition (silicon oxide, silicon nitride, silicon oxynitride or silicon oxycarbide), a process gas may be flowed into the first plasma region 415 through a gas inlet assembly 405. The process gas may be excited prior to entering the first plasma region 415 within a remote plasma system (RPS) 400. A lid 412 and showerhead 425 are shown according to disclosed embodiments. The lid 412 is depicted (FIG. 4A) with an applied AC voltage source and the showerhead is grounded, consistent with the first position of the electrical switch in FIG. 3A. An insulating ring 420 is positioned between the lid 412 and the showerhead 425 enabling a capacitively coupled plasma (CCP) to be formed in the first plasma region.

A silicon-containing precursor may be flowed into the second plasma region 433 through tubes 430 extending from the sides 435 of the processing chamber. Excited species derived from the process gas travel through holes in the showerhead 425 and react with the silicon-containing precursor flowing through the second plasma region 433. The diameter of holes in the showerhead 425 may be below 12 mm, may be between 0.25 mm and 8 mm, and may be between 0.5 mm and 6 mm in different embodiments. The thickness of the showerhead can vary quite a bit but the length of the diameter of the holes may be about the diameter of the holes or less, increasing the density of the excited species derived from the process gas within the second plasma region 433. Little or no plasma is present in the second plasma region 433 due to the position of the switch (FIG. 3A). Excited derivatives of the process gas and the silicon-containing precursor combine in the region above the substrate and, on occasion, on the substrate to form a flowable film on the substrate. As the film grows, more recently added material possesses a higher mobility than underlying material. Mobility decreases as organic content is reduced by evaporation. Gaps may be filled by the flowable film using this technique without leaving traditional densities of organic content within the film after deposition is completed. A curing step may still be used to further reduce or remove the organic content from a deposited film.

Exciting the process gas in the first plasma region 415 alone or in combination with the remote plasma system (RPS) provides several benefits. The concentration of the excited species derived from the process gas may be increased within the second plasma region 433 due to the plasma in the first plasma region 415. This increase may result from the location of the plasma in the first plasma region 415. The second plasma region 433 is located closer to the first plasma region 415 than the remote plasma system (RPS) 400, leaving less time for the excited species to leave excited states through collisions with other gas molecules, walls of the chamber and surfaces of the showerhead.

The uniformity of the concentration of the excited species derived from the process gas may also be increased within the second plasma region 433. This may result from the shape of the first plasma region 415, which is more similar to the shape of the second plasma region 433. Excited species created in the remote plasma system (RPS) 400 travel greater distances in order to pass through holes near the edges of the showerhead 425 relative to species that pass through holes near the center of the showerhead 425. The greater distance results in a reduced excitation of the excited species and, for example, may result in a slower growth rate near the edge of a substrate. Exciting the process gas in the first plasma region 415 mitigates this variation.

In addition to the process gas and silicon-containing precursor there may be other gases introduced at varied times for varied purposes. A treatment gas may be introduced to remove unwanted species from the chamber walls, the substrate, the deposited film and/or the film during deposition. The treatment gas may comprise at least one of the gases from the group: H₂, an H₂/N₂ mixture, NH₃, NH₄OH, O₃, O₂, H₂O₂ and water vapor. A treatment gas may be excited in a plasma and then used to reduce or remove a residual organic content from the deposited film. In other disclosed embodiments the treatment gas may be used without a plasma. When the treatment gas includes water vapor, the delivery may be achieved using a mass flow meter (MFM) and injection valve or by commercially available water vapor generators.

FIG. 4B is a cross-sectional view of a process chamber with a plasma in the second plasma region 433 consistent with the switch position shown in FIG. 3B. A plasma may be used in the second plasma region 433 to excite a treatment gas delivered through the tubes 430 extending from the sides 435 of the processing chamber. Little or no plasma is present in the first plasma region 415 due to the position of the switch (FIG. 3B). Excited species derived from the treatment gas react with the film on the substrate 455 and remove organic compounds from the deposited film. Herein this process may be referred to as treating or curing the film.

The tubes 430 in the second plasma region 433 comprise insulating material, such as aluminum nitride or aluminum oxide, in some disclosed embodiments. An insulating material reduces the risk of sparking for some substrate processing chamber architectures.

The treatment gas may also be introduced through the gas inlet assembly 405 into the first plasma region 415. In disclosed embodiments the treatment gas may be introduced through the gas inlet assembly 405 alone or in combination with a flow of treatment gas through the tubes 430 extending from the walls 435 of the second plasma region 433. A treatment gas flowing through the first plasma region 415 and then through the showerhead 430 to treat a deposited film may be excited in a plasma in the first plasma region 415 or alternatively in a plasma in the second plasma region 433.

In addition to treating or curing the substrate 455, a treatment gas may be flowed into the second plasma region 433 with a plasma present to clean the interior surfaces (e.g. walls 435, showerhead 425, pedestal 465 and tubes 430) of the second plasma region 433. Similarly, a treatment gas may be flowed into the first plasma region 415 with a plasma present to clean the interior of the surfaces (e.g. lid 412, walls 420 and showerhead 425) of the first plasma region 415. In disclosed embodiments, a treatment gas is flowed into the second plasma region 433 (with a plasma present) after a second plasma region maintenance procedure (clean and/or season) to remove residual fluorine from the interior surfaces of the second plasma region 433. As part of a separate procedure or a separate step (possibly sequential) of the same procedure, the treatment gas is flowed into the first plasma region 415 (with a plasma present) after a first plasma region maintenance procedure (clean and/or season) to remove residual fluorine from the interior surfaces of the first plasma region 415. Generally, both regions will be in need of cleaning or seasoning at the same time and the treatment gas may treat each region sequentially before substrate processing resumes.

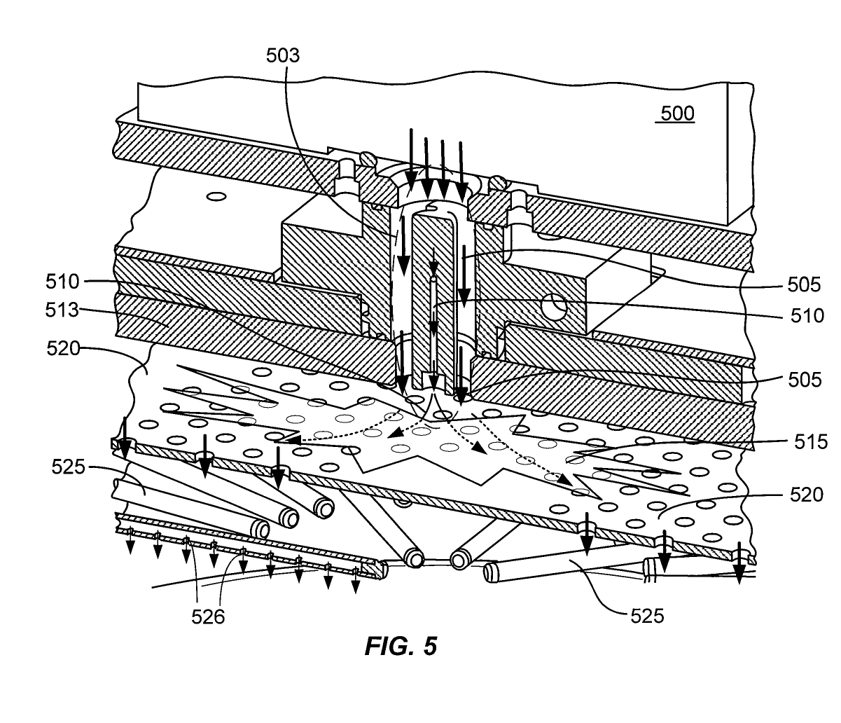

The aforementioned treatment gas processes use a treatment gas in process steps distinct from the deposition step. A treatment gas may also be used during deposition to remove organic content from the growing film. FIG. 5 shows a close-up perspective view of the gas inlet assembly 503 and the first plasma region 515. The gas inlet assembly 503 is shown in finer detail revealing two distinct gas flow channels 505, 510. In an embodiment, the process gas is flowed into the first plasma region 515 through an exterior channel 505. The process gas may or may not be excited by the RPS 500. A treatment gas may flow into the first plasma region 515 from an interior channel 510, without being excited by the RPS 500. The locations of the exterior channel 505 and the interior channel 510 may be arranged in a variety of physical configurations (e.g. the RPS excited gas may flow through the interior channel in disclosed embodiments) such that only one of the two channels flows through the RPS 500.

Both the process gas and the treatment gas may be excited in a plasma in the first plasma region 515 and subsequently flow into the second plasma region through holes in the showerhead 520. The purpose of the treatment gas is to remove unwanted components (generally organic content) from the film during deposition. In the physical configuration shown in FIG. 5, the gas from the interior channel 510 may not contribute appreciably to the film growth, but may be used to scavenge fluorine, hydrogen and/or carbon from the growing film.

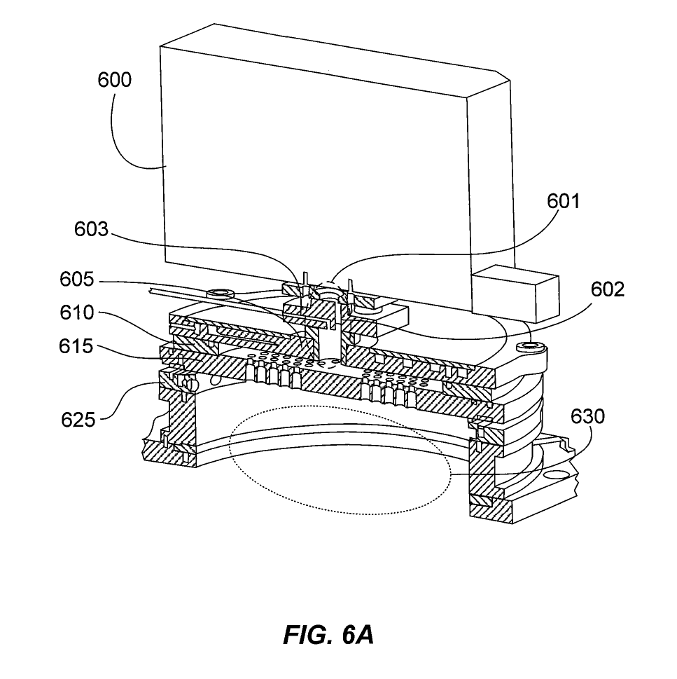

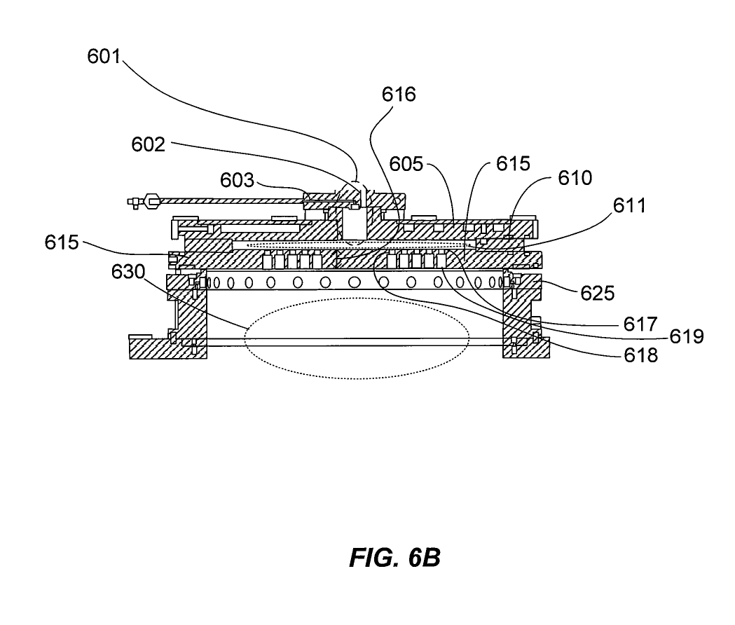

FIG. 6A is a perspective view and FIG. 6B is a cross-sectional view, both of a chamber-top assembly for use with a processing chamber according to disclosed embodiments. A gas inlet assembly 601 introduces gas into the first plasma region 611. Two distinct gas supply channels are visible within the gas inlet assembly 601. A first channel 602 carries a gas that passes through the remote plasma system RPS 600, while a second channel 603 bypasses the RPS 600. The first channel 602 may be used for the process gas and the second channel 603 may be used for a treatment gas in disclosed embodiments. The lid 605 and showerhead 615 are shown with an insulating ring 610 in between, which allows an AC potential to be applied to the lid 605 relative to the showerhead 615. The side of the substrate processing chamber 625 is shown with a gas distribution channel from which tubes may be mounted pointing radially inward. Tubes are not shown in the views of FIGS. 6A-B.

The showerhead 615 of FIGS. 6A-B is thicker than the length of the smallest diameter 617 of the holes in this disclosed embodiment. In order to maintain a significant concentration of excited species penetrating from the first plasma region 611 to the second plasma region 630, the length 618 of the smallest diameter 617 of the holes may be restricted by forming larger holes 619 part way through the showerhead 615. The length of the smallest diameter 617 of the holes may be the same order of magnitude as the smallest diameter 617 of the holes or less in disclosed embodiments.

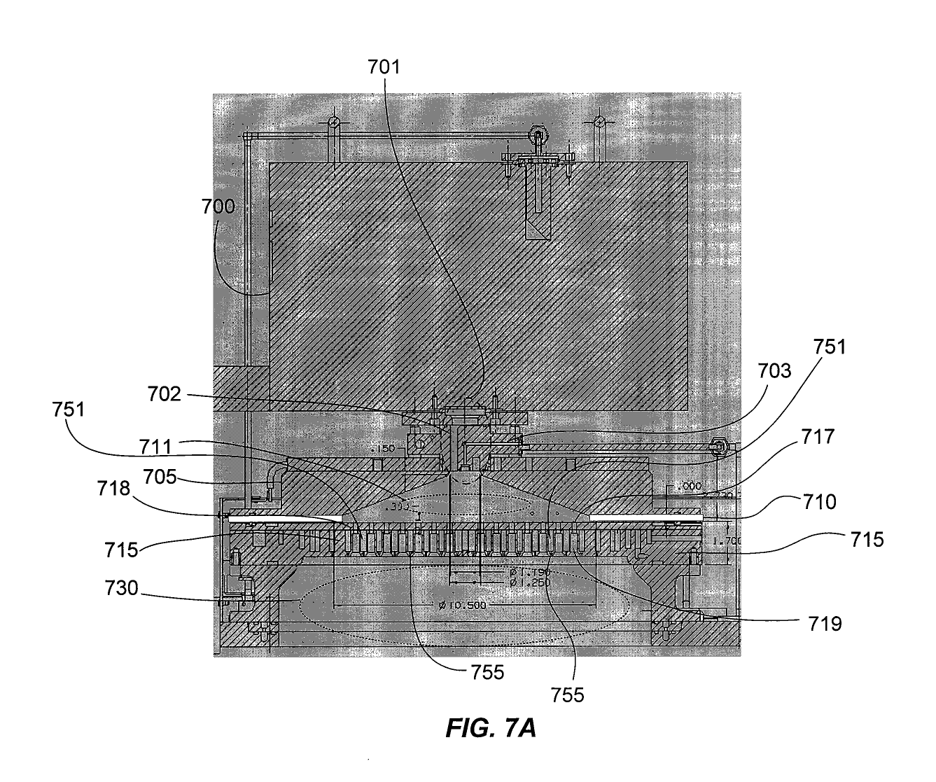

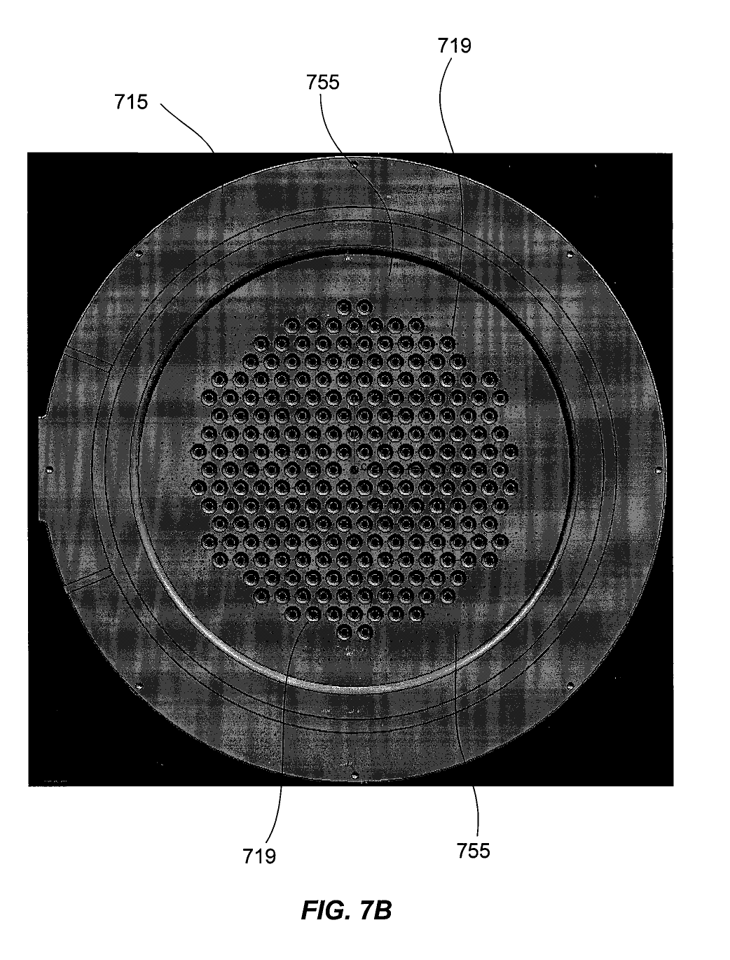

FIG. 7A is another cross-sectional view of a dual-source lid for use with a processing chamber according to disclosed embodiments. A gas inlet assembly 701 introduces gas into the first plasma region 711. Two distinct gas supply channels are visible within the gas inlet assembly 701. A first channel 702 carries a gas that passes through the remote plasma system RPS 700, while a second channel 703 bypasses the RPS 700. The first channel 702 may be used for the process gas and the second channel 703 may be used for a treatment gas in disclosed embodiments. The lid 705 and showerhead 715 are shown with an insulating ring 710 in between, which allows an AC potential to be applied to the lid 705 relative to the showerhead 715.

The showerhead 715 of FIG. 7A has through-holes similar to those in FIGS. 6A-B to allow excited derivatives of gases (such as a process gas) to travel from first plasma region 711 into second plasma region 730. The showerhead 715 also has one or more hollow volumes 751 which can be filled with a vapor or gas (such as a silicon-containing precursor) and pass through small holes 755 into second plasma region 730 but not into first plasma region 711. Hollow volumes 751 and small holes 755 may be used in place of tubes for introducing silicon-containing precursors into second plasma region 730. Showerhead 715 is thicker than the length of the smallest diameter 717 of the through-holes in this disclosed embodiment. In order to maintain a significant concentration of excited species penetrating from the first plasma region 711 to the second plasma region 730, the length 718 of the smallest diameter 717 of the through-holes may be restricted by forming larger holes 719 part way through the showerhead 715. The length of the smallest diameter 717 of the through-holes may be the same order of magnitude as the smallest diameter 617 of the through-holes or less in disclosed embodiments.

In embodiments, the number of through-holes may be between about 60 and about 2000. Through-holes may have a variety of shapes but are most easily made round. The smallest diameter of through holes may be between about 0.5 mm and about 20 mm or between about 1 mm and about 6 mm in disclosed embodiments. There is also latitude in choosing the cross-sectional shape of through-holes, which may be made conical, cylindrical or a combination of the two shapes. The number of small holes 755 used to introduce a gas into second plasma region 730 may be between about 100 and about 5000 or between about 500 and about 2000 in different embodiments. The diameter of the small holes may be between about 0.1 mm and about 2 mm.

FIG. 7B is a bottom view of a showerhead 715 for use with a processing chamber according to disclosed embodiments. Showerhead 715 corresponds with the showerhead shown in FIG. 7A. Through-holes 719 have a larger inner-diameter (ID) on the bottom of showerhead 715 and a smaller ID at the top. Small holes 755 are distributed substantially evenly over the surface of the showerhead, even amongst the through-holes 719 which helps to provide more even mixing than other embodiments described herein.

### Exemplary Substrate Processing System

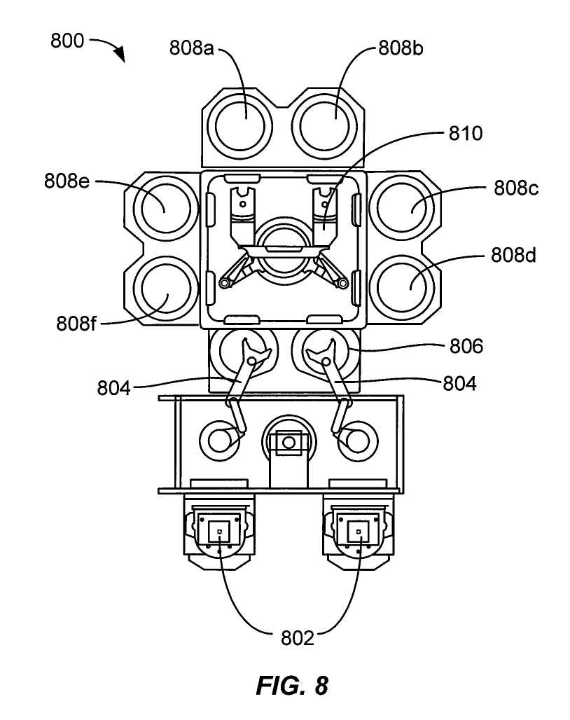

Embodiments of the deposition systems may be incorporated into larger fabrication systems for producing integrated circuit chips. FIG. 8 shows one such system 800 of deposition, baking and curing chambers according to disclosed embodiments. In the figure, a pair of FOUPs (front opening unified pods) 802 supply substrate substrates (e.g., 300 mm diameter wafers) that are received by robotic arms 804 and placed into a low pressure holding area 806 before being placed into one of the wafer processing chambers 808a-f. A second robotic arm 810 may be used to transport the substrate wafers from the holding area 806 to the processing chambers 808a-f and back.

The processing chambers 808a-f may include one or more system components for depositing, annealing, curing and/or etching a flowable dielectric film on the substrate wafer. In one configuration, two pairs of the processing chamber (e.g., 808c-d and 808e-f) may be used to deposit the flowable dielectric material on the substrate, and the third pair of processing chambers (e.g., 808a-b) may be used to anneal the deposited dialectic. In another configuration, the same two pairs of processing chambers (e.g., 808c-d and 808e-f) may be configured to both deposit and anneal a flowable dielectric film on the substrate, while the third pair of chambers (e.g., 808a-b) may be used for UV or E-beam curing of the deposited film. In still another configuration, all three pairs of chambers (e.g., 808a-f) may be configured to deposit an cure a flowable dielectric film on the substrate. In yet another configuration, two pairs of processing chambers (e.g., 808c-d and 808e-f) may be used for both deposition and UV or E-beam curing of the flowable dielectric, while a third pair of processing chambers (e.g. 808a-b) may be used for annealing the dielectric film. It will be appreciated, that additional configurations of deposition, annealing and curing chambers for flowable dielectric films are contemplated by system 800.

In addition, one or more of the process chambers 808a-f may be configured as a wet treatment chamber. These process chambers include heating the flowable dielectric film in an atmosphere that include moisture. Thus, embodiments of system 800 may include wet treatment chambers 808a-b and anneal processing chambers 808c-d to perform both wet and dry anneals on the deposited dielectric film.

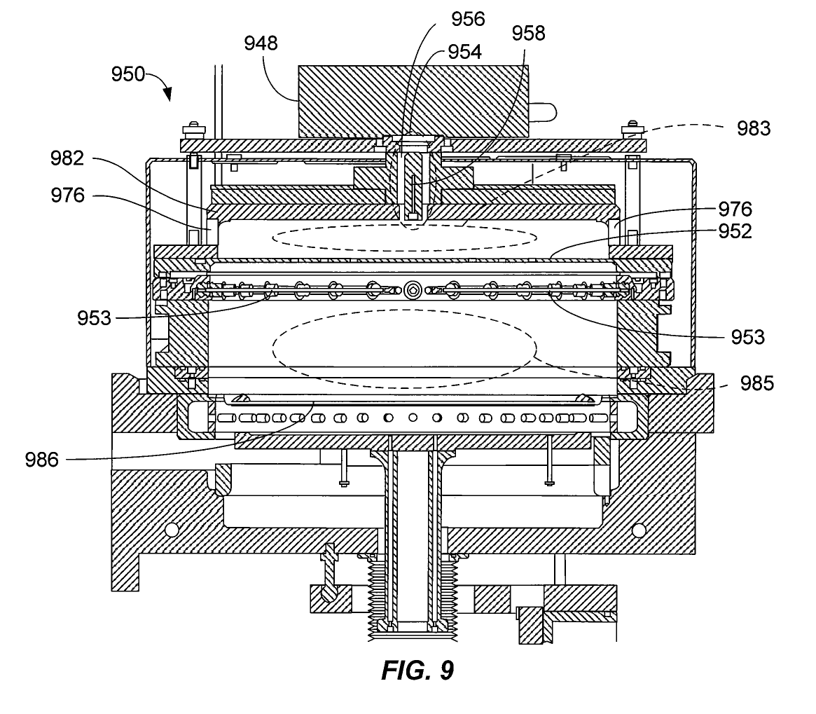

FIG. 9 is a substrate processing chamber 950 according to disclosed embodiments. A remote plasma system (RPS) 948 may process a gas which then travels through a gas inlet assembly 954. More specifically, the gas travels through channel 956 into a first plasma region 983. Below the first plasma region 983 is a perforated partition (a showerhead) 952 to maintain some physical separation between the first plasma region 983 and a second plasma region 985 beneath the showerhead 952. The showerhead allows a plasma present in the first plasma region 983 to avoid directly exciting gases in the second plasma region 985, while still allowing excited species to travel from the first plasma region 983 into the second plasma region 985.

The showerhead 952 is positioned above side nozzles (or tubes) 953 protruding radially into the interior of the second plasma region 985 of the substrate processing chamber 950. The showerhead 952 distributes the precursors through a plurality of holes that traverse the thickness of the plate. The showerhead 952 may have, for example from about 10 to 10000 holes (e.g., 200 holes). In the embodiment shown, the showerhead 952 may distribute a process gas which contains oxygen, hydrogen and/or nitrogen or derivatives of such process gases upon excitation by a plasma in the first plasma region 983. In embodiments, the process gas may contain one or more of oxygen (O₂), ozone (O₃), N₂O, NO, NO₂, NH₃, NₓH_{y} including N₂H₄, silane, disilane, TSA and DSA.

The tubes 953 may have holes in the end (closest to the center of the second plasma region 985) and/or holes distributed around or along the length of the tubes 953. The holes may be used to introduce a silicon-containing precursor into the second plasma region. A film is created on a substrate supported by a pedestal 986 in the second plasma region 985 when the process gas and its excited derivatives arriving through the holes in the showerhead 952 combine with the silicon-containing precursor arriving through the tubes 953.

The top inlet 954 may have two or more independent precursor (e.g., gas) flow channels 956 and 958 that keep two or more precursors from mixing and reaction until they enter the first plasma region 983 above the showerhead 952. The first flow channel 956 may have an annular shape that surrounds the center of inlet 954. This channel may be coupled to the remote plasma system (RPS) 948 that generates a reactive species precursor which flows down the channel 956 and into the first plasma region 983 above the showerhead 952. The second flow channel 958 may be cylindrically shaped and may be used to flow a second precursor to the first plasma region 983. This flow channel may start with a precursor and/or carrier gas source that bypasses a reactive species generating unit. The first and second precursors are then mixed and flow through the holes in the plate 952 to the second plasma region.

The showerhead 952 and top inlet 954 may be used to deliver the process gas to the second plasma region 985 in the substrate processing chamber 950. For example, first flow channel 956 may deliver a process gas that includes one or more of atomic oxygen (in either a ground or electronically excited state), oxygen (O₂), ozone (O₃), N₂O, NO, NO₂, NH₃, NₓH_{y} including N₂H₄, silane, disilane, TSA and DSA. The process gas may also include a carrier gas such as helium, argon, nitrogen (N₂), etc. The second channel 958 may also deliver a process gas, a carrier gas, and/or a treatment gas used to remove an unwanted component from the growing or as-deposited film.

For a capacitively coupled plasma (CCP), an electrical insulator 976 (e.g. a ceramic ring) is placed between the showerhead and the conducting top portion 982 of the processing chamber to enable an voltage difference to be asserted. The presence of the electrical insulator 976 ensures that a plasma may be created by the RF power source inside the first plasma region 983. Similarly, a ceramic ring may also be placed between the showerhead 952 and the pedestal 986 (not shown in FIG. 9) to allow a plasma to be created in the second plasma region 985. This may be placed above or below the tubes 953 depending on the vertical location of the tubes 953 and whether they have metal content which could result in sparking.

A plasma may be ignited either in the first plasma region 983 above the showerhead or the second plasma region 985 below the showerhead and the side nozzles 953. An AC voltage typically in the radio frequency (RF) range is applied between the conducting top portion 982 of the processing chamber and the showerhead 952 to ignite the a plasma in the first plasma region 983 during deposition. The top plasma is left at low or no power when the bottom plasma 985 is turned on to either cure a film or clean the interior surfaces bordering the second plasma region 985. A plasma in the second plasma region 985 is ignited by applying an AC voltage between the showerhead 952 and the pedestal 986 (or bottom of the chamber).

A gas in an “excited state” as used herein describes a gas wherein at least some of the gas molecules are in vibrationally-excited, dissociated and/or ionized states. A gas may be a combination of two or more gases.

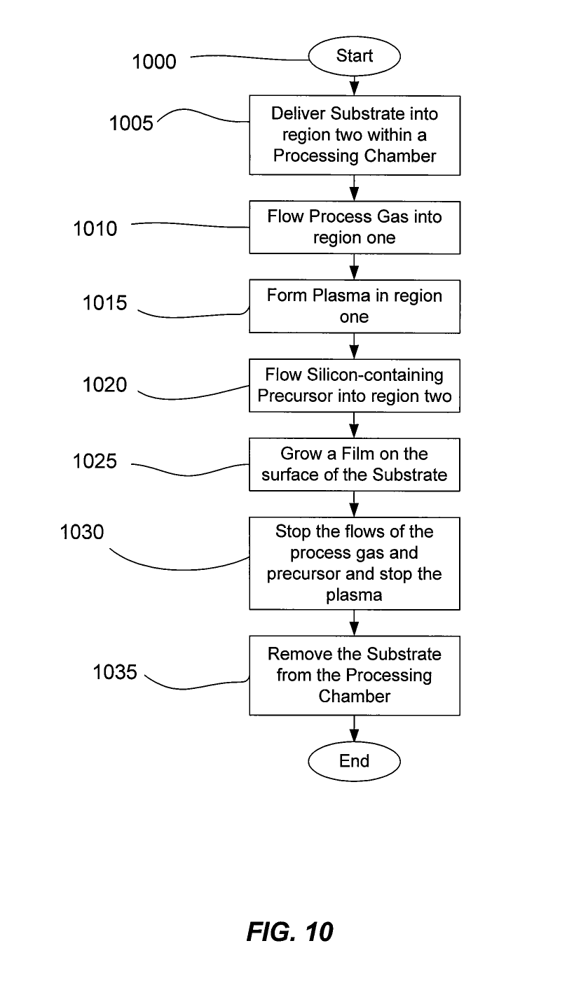

Disclosed embodiments include methods which may pertain to deposition, etching, curing, and/or cleaning processes. FIG. 10 is a flow chart of a deposition process according to disclosed embodiments. A substrate processing chamber that is divided into at least two compartments is used to carry out the methods described herein. The substrate processing chamber may have a first plasma region and a second plasma region. Both the first plasma region and the second plasma region may have plasmas ignited within the regions.

The process shown in FIG. 10 begins with the delivery of a substrate into a substrate processing chamber (Step 1005). The substrate is placed in the second plasma region after which a process gas may be flowed (Step 1010) into the first plasma region. A treatment gas may also be introduced into either the first plasma region or the second plasma region (step not shown). A plasma may then initiated (Step 1015) in the first plasma region but not in the second plasma region. A silicon-containing precursor is flowed into the second plasma region 1020. The timing and order of steps 1010, 1015 and 1020 may be adjusted without deviating from the spirit of the invention. Once the plasma is initiated and the precursors are flowing, a film is grown 1025 on the substrate. After a film is grown 1025 to a predetermined thickness or for a predetermined time, the plasmas and gas flows are stopped 1030 and the substrate may be removed 1035 from the substrate processing chamber. Before the substrate is removed, the film may be cured in the process described next.

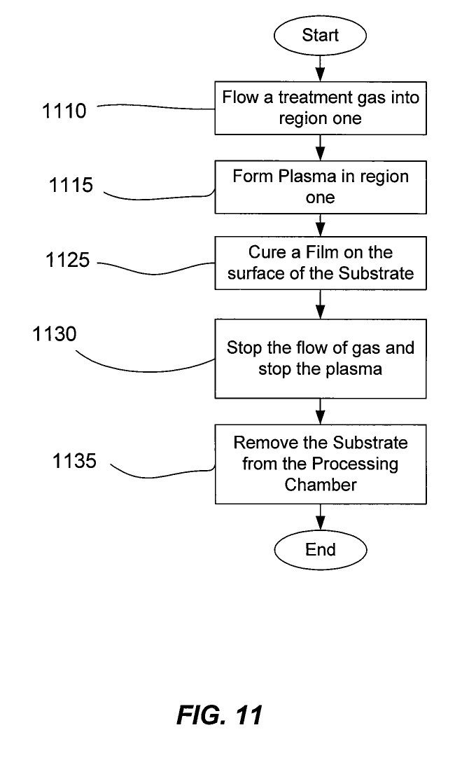

FIG. 11 is a flow chart of a film curing process according to disclosed embodiments. The start 1100 of this process may be just before the substrate is removed 1035 in the method shown in FIG. 10. This process may also start 1100 by a substrate into the second plasma region of the processing chamber. In this case the substrate may have been processed in another processing chamber. A treatment gas (possible gases described earlier) is flowed 1110 into the first plasma region and a plasma is initiated 1115 in the first plasma region (again the timing/order may be adjusted). Undesirable content in the film is then removed 1125. In some disclosed embodiments, this undesirable content is organic and the process involves curing or hardening 1125 the film on the substrate. The film may shrink during this process. The flow of the gas and the plasma are stopped 1130 and the substrate may be removed 1135 from the substrate processing chamber.

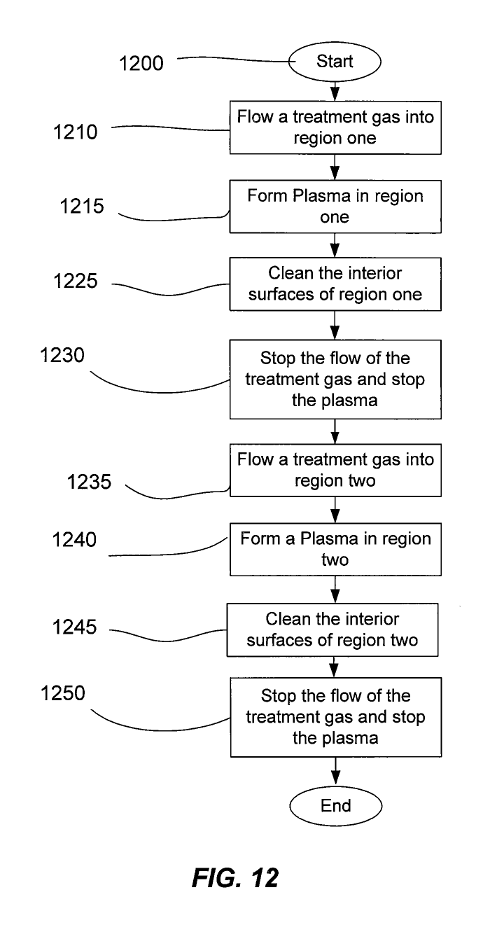

FIG. 12 is a flow chart of a chamber cleaning process according to disclosed embodiments. The start 1200 of this process may occur after a chamber is cleaned or seasoned which often occur after a preventative maintenance (PM) procedure or an unplanned event. Because the substrate processing chamber has two compartments which may not be able to support plasmas in the first plasma region and the second plasma region simultaneously, a sequential process may be needed to clean both regions. A treatment gas (possible gases described earlier) is flowed 1210 into the first plasma region and a plasma is initiated 1215 in the first plasma region (again the timing/order may be adjusted). The interior surfaces within the first plasma region are cleaned 1225 before the flow of the treatment gas and the plasma are stopped 1230. The process is repeated for the second plasma region. The treatment gas is flowed 1235 into the second plasma region and a plasma is initiated 1240 therein. The interior surfaces of the second plasma region are cleaned 1245 and the treatment gas flow and plasma are stopped 1250. Interior surface cleaning procedures may be conducted to clean fluorine from the interior surfaces of the substrate processing chamber as well as other leftover contaminants from troubleshooting and maintenance procedures.

Having disclosed several embodiments, it will be recognized by those of skill in the art that various modifications, alternative constructions, and equivalents may be used without departing from the spirit of the disclosed embodiments. Additionally, a number of well known processes and elements have not been described in order to avoid unnecessarily obscuring the present invention. Accordingly, the above description should not be taken as limiting the scope of the invention.

Where a range of values is provided, it is understood that each intervening value, to the tenth of the unit of the lower limit unless the context clearly dictates otherwise, between the upper and lower limits of that range is also specifically disclosed. Each smaller range between any stated value or intervening value in a stated range and any other stated or intervening value in that stated range is encompassed. The upper and lower limits of these smaller ranges may independently be included or excluded in the range, and each range where either, neither or both limits are included in the smaller ranges is also encompassed within the invention, subject to any specifically excluded limit in the stated range. Where the stated range includes one or both of the limits, ranges excluding either or both of those included limits are also included.

As used herein and in the appended claims, the singular forms “a”, “an”, and “the” include plural referents unless the context clearly dictates otherwise. Thus, for example, reference to “a process” includes a plurality of such processes and reference to “the motor” includes reference to one or more motors and equivalents thereof known to those skilled in the art, and so forth.

Also, the words “comprise,” “comprising,” “include,” “including,” and “includes” when used in this specification and in the following claims are intended to specify the presence of stated features, integers, components, or steps, but they do not preclude the presence or addition of one or more other features, integers, components, steps, acts, or groups.

What is claimed is:

1. A substrate processing system comprising:
a processing chamber having an interior capable of holding an internal chamber pressure different from an external chamber pressure;
a remote plasma system operable to generate a plasma outside the interior of the processing chamber;
a first process gas channel operable to transport a first process gas from the remote plasma system to the interior of the processing chamber, and
a second process gas channel operable to transport a second process gas that is not treated by the remote plasma system; wherein the second process gas channel has a distal end that opens into the interior of the processing chamber, and that is at least partially surrounded by the first process gas channel.

2. The substrate processing system of claim 1, wherein a distal portion of the first process gas channel has an annular shape.

3. The substrate processing system of claim 1, wherein a distal portion of the second process gas channel has a cylindrical shape.

4. The substrate processing system of claim 1, wherein the distal end of the second process gas channel is positioned concentrically inside the first process gas channel.

5. The substrate processing system of claim 1, wherein the first and second process gases flow in a substantially parallel direction when they exit the first and second channels.

6. The substrate processing system of claim 1, wherein the first and second process gas channels open into the interior of the processing chamber upstream of a showerhead that partitions the interior of the processing chamber into first and second plasma region.

7. A substrate processing system comprising:
a processing chamber having an interior capable of holding an internal chamber pressure which can be different from an external chamber pressure;
a first conducting surface within the processing chamber;
a second conducting surface within the processing chamber; and
a showerhead positioned between the first conducting surface and the second conducting surface to define a first plasma region and a second plasma region, wherein:
the first plasma region is disposed between the showerhead and the first conducting surface;
the second plasma region is disposed between the showerhead and the second conducting surface;
the showerhead comprises an electrically conducting material and is electrically insulated from the first conducting surface unless an electrical connection is made with an electrical switch; and
the showerhead is electrically insulated from the second conducting surface unless an electrical connection is made with an electrical switch.

8. The substrate processing system of claim 7, further comprising a gas handling system, the gas handling system comprising:
a first channel for conducting a process gas;
a second channel for conducting a treatment gas; and
an RPS for exciting the process gas.

9. The substrate processing system of claim 7, wherein the showerhead is at a similar electrical potential to the first conducting surface resulting in little or no plasma in the first plasma region.

10. The substrate processing system of claim 7, wherein the showerhead is at a similar electrical potential to the second conducting surface resulting in little or no plasma in the second plasma region.

11. The substrate processing system of claim 7, wherein the electrical switch is located outside the processing chamber.

12. The substrate processing system of claim 7, wherein the second conducting surface is held at an electrical ground and the electrical switch has at least two possible positions, wherein:
a first position of the electrical switch connects a radio frequency power supply to the first conducting surface and an electrical ground to the showerhead to create a first plasma in the first plasma region;
a second position of the electrical switch connects the radio frequency power

13. The substrate processing system of claim 7, wherein plasmas in the first plasma region and the second plasma region are created with radio frequency (RF) power supplies.

14. The substrate processing system of claim 7, wherein a plasma is created in one of the two plasma regions at any instant of time.

15. The substrate processing system of claim 7, wherein the substrate processing system comprises a pumping system coupled to the processing chamber and adapted to remove material from the processing chamber.

16. The substrate processing system of claim 7, wherein the system comprises a remote plasma system external to the processing chamber and fluidly coupled to the first plasma region, wherein the remote plasma system is adapted to supply a gas comprising reactants in an excited state, to the first plasma region.

17. A processing chamber partitioned into separate plasma regions, the processing chamber comprising:
a partition that divides the processing chamber into a first plasma region and a second plasma region, wherein each of the regions is operable to contain separate plasmas;
a plurality of holes in the partition to permit gases to pass from the first plasma region to the second plasma region; and
a substrate pedestal occupying a portion of the second plasma region.

18. The processing chamber of claim 17, wherein plasmas in the first plasma region and the second plasma region are inductively coupled.

19. The processing chamber of claim 17, wherein plasmas in the first plasma region and the second plasma region are capacitively coupled.

20. The processing chamber of claim 17, wherein the processing chamber is coupled to a controller operable to execute a program for generating a first plasma in the first plasma region as part of a dielectric deposition process, and generating a second plasma in the second plasma region as part of a curing or cleaning process performed after the first plasma has been stopped.

21. The processing chamber of claim 17, wherein the processing chamber comprises a gas inlet to supply a process gas to the first plasma region.

22. The processing chamber of claim 21, wherein the gas inlet is coupled to a remote plasma system operable to supply a process gas in an excited state to the first plasma region.

23. The processing chamber of claim 21, wherein the gas inlet is fluidly coupled to a fluid supply system operable to supply the process chamber with a process gas comprising at least one gas selected from the group consisting of O₂, O₃, N₂O, NO, NO₂, NH₃, NH₄OH, NₓH_{y}, silane, disilane, TSA, DSA, H₂, N₂, H₂O₂ and water vapor.

24. The processing chamber of claim 17, wherein the processing chamber comprises one or more nozzles positioned above the substrate pedestal in the second plasma region and operable to deliver a process gas to the second plasma region.

25. The processing chamber of claim 24, wherein the one or more nozzles are fluidly coupled to a fluid supply system operable to supply the processing chamber with a carbon and silicon containing precursor.
